(19) United States
(12) Patent Application Publication
(10) Pub. No.: US 2026/0182448 A1
(43) Pub. Date: Jun. 25, 2026

(54) BOTTOM SIDE SILICON REJECTS RING STIFFENER FOR PACKAGE WARPAGE MITIGATION

(71) Applicant: Intel Corporation, Santa Clara, CA (US)

(72) Inventors: Min Suet LIM, Penang (MY); Kavitha NAGARAJAN, Bangalore (IN); Stephan STOECKL, Schwandorf (DE); Seok Ling LIM, Penang (MY); Eng Huat GOH, Penang (MY)

(21) Appl. No.: 19/001,253

(22) Filed: Dec. 24, 2024

(51) Int. Cl. H01L 23/18; H01L 23/04; H01L 23/538

(52) U.S. Cl. CPC H10W 76/42; H10W 70/611; H10W 70/635; H10W 70/65; H10W 76/12

(57) ABSTRACT

Embodiments disclosed herein may include an apparatus that includes a substrate, such as a package substrate. In an embodiment, a ring may be on the substrate. The ring may be a stiffener used to improve planarity of the package substrate. In an embodiment, the ring may include a matrix material, and a plurality of semiconductor chips may be embedded in the matrix material. The semiconductor chips may be recycled pieces of semiconductor material.

### BACKGROUND

Large area package substrates require stiffeners in order to maintain the desired planarity for proper assembly and reliability. Components that are mounted adjacent to the stiffener may require underfill for reliability purposes as well. Accordingly, a keep out zone (KOZ) is necessary in order to allow a dispensing tool to be inserted between the component and an edge of the stiffener. The KOZ is otherwise unoccupied space and results in a lower area utilization of the package substrate. As such, the package substrate needs to be increased in area to accommodate the desired components. Larger packages are generally undesirable in many application spaces.

### BRIEF DESCRIPTION OF THE DRAWINGS

FIG. 1 is a plan view illustration of a package substrate with a stiffener and a plurality of components mounted to the stiffener, in accordance with an embodiment.

FIG. 2A is a plan view illustration of a bottom side of a package substrate with a reconstituted semiconductor stiffener ring, in accordance with an embodiment.

FIG. 2B is a plan view illustration of a bottom side of a package substrate with a reconstituted semiconductor stiffener ring, in accordance with an additional embodiment.

FIG. 3A is a cross-sectional illustration of a recycled semiconductor chip that is used in a reconstituted semiconductor stiffener ring, in accordance with an embodiment.

FIG. 3B is a cross-sectional illustration of a recycled semiconductor chip that is used in a reconstituted semiconductor stiffener ring, in accordance with an additional embodiment.

FIGS. 4A-4D are illustrations depicting a process for forming a reconstituted semiconductor stiffener strip, in accordance with an embodiment.

FIG. 5 is a flow diagram depicting a process for forming a reconstituted semiconductor stiffener strip, in accordance with an embodiment.

FIGS. 6A-6D are illustrations depicting a process for forming a reconstituted semiconductor stiffener strip from a semiconductor powder, in accordance with an embodiment.

FIG. 7 is a flow diagram depicting a process for forming a reconstituted semiconductor stiffener strip from a semiconductor powder, in accordance with an embodiment.

FIG. 8 is a cross-sectional illustration of an electronic system with a reconstituted semiconductor stiffener on a bottom of a package substrate, in accordance with an embodiment.

FIG. 9 is a schematic of a computing device built in accordance with an embodiment.

### EMBODIMENTS OF THE PRESENT DISCLOSURE

Described herein are electronic systems with reconstituted semiconductor stiffeners on a package substrate, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, many package substrates require a stiffener in order to meet planarity specifications. The stiffener occupies area on the package substrate. Additionally, components need to be spaced apart from the stiffener by a distance (referred to as the keep out zone (KOZ)) in order to allow space for a dispensing tool to dispense underfill below the neighboring components. Typically, the KOZ is between 1.5 mm and 2.0 mm.

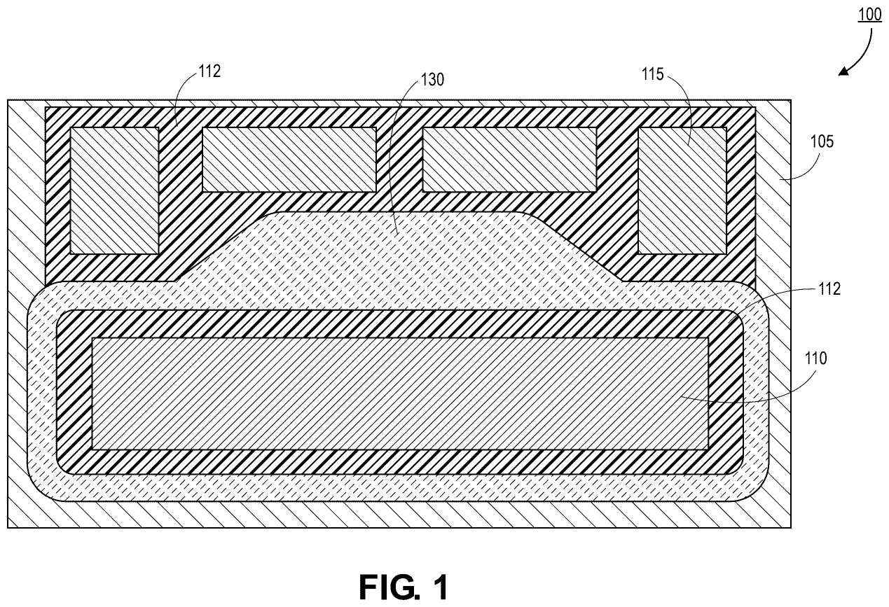

An example of an electronic system 100 is shown in FIG. 1. As shown, a die 110 may be provided on a package substrate 105 and surrounded by a stiffener 130. An underfill 112 fills the space between the stiffener 130 and the die 110. Additional components 115 may be provided outside of the stiffener 130. For example, the die 110 may be a processor, and the additional components 115 may be memory dies or the like. The components 115 may be electrically coupled to the die 110 through routing (not shown) within the package substrate 105. Underfill 112 may also surround the components 115. As such, a KOZ is provided between edges of the components 115 and the outer edge of the stiffener 130.

Typically, the stiffener 130 is needed on the top side of the package substrate 105, as shown in FIG. 1. This is because the bottom side of the package substrate 105 is dedicated to the layout of interconnects (e.g., solder bumps, pins, or the like) for power delivery, signal delivery, etc. Placing a block of material on the bottom side of the package substrate 105 to improve warpage of the die 110 disrupts the interconnect layout and may not allow for a sufficient interconnect density. Accordingly, the stiffening effect is typically implemented from the top side. Since the stiffener 130 needs to be relatively large, the useable area on the package substrate 105 is decreased. This may lead to the need for larger package substrates, which is usually undesirable.

Accordingly, embodiments disclosed herein may include a bottom side stiffener that has a ring or frame-like shape. The ring shape may occupy a relatively small area since the interior of the stiffener is cut out to form the ring shape. In some embodiments, the shape of the stiffener may be designed to fit between the interconnects on the bottom side of the package substrate or to occupy the space of a relatively low number of interconnects. The ring shape also allows for the interconnects to be provided directly under the die and allows for direct vertical power routing from interconnects to the overlying die.

Further, embodiments disclosed herein may comprise a stiffener that includes a semiconductor material (e.g., silicon). The use of a semiconductor material allows for close coefficient of thermal expansion (CTE) matching with the overlying die 110 and/or components 115. This provides better planarity for the package substrate 105. It has been shown that the warpage of the overlying die 110 is the most problematic at the edges of the die 110. Accordingly, the stiffener may be positioned under the edges of the die 110 to provide the most effective use of the space. That is, the die 110 may be at least partially within a footprint defined by an outer perimeter of the stiffener.

Moving the stiffener ring to the bottom side of the package allows for the stiffener 130 on the top surface of the package substrate 105 to have reduced dimensions and/or to be omitted. This provides more useable area on the package substrate 105. As such, more functionality can be added to the electronic system 100 and/or the footprint and/or thickness of the electronic system 100 may be reduced.

It is to be appreciated that silicon is a relatively expensive material. As such, the fabrication of monolithic semiconductor stiffener rings may not be desirable in some product segments due to the high manufacturing and material costs. However, the semiconductor industry includes a significant amount of semiconductor waste material. For example, the outer edges of semiconductor wafers that are processed to form dies and/or other components may include defective devices, devices in a dedicated exclusion zone (which are not intended to be useable), test regions of the wafer, and/or the like. Typically, such non-useable regions of the wafer are wasted.

Accordingly, embodiments disclosed herein may recycle such unusable regions of the wafer in order to fabricate reconstituted semiconductor stiffener rings. In one embodiment, a plurality semiconductor reject pieces can be assembled as a mosaic (e.g., held together with an epoxy and/or molding material) to form the reconstituted semiconductor stiffener rings. The semiconductor reject pieces may also be ground into a powder that is held together with a bonding matrix (e.g., an epoxy or the like). Such processes allow for a cost effective integration of waste silicon into the electronic system, while also providing a sustainable use for waste product from other semiconductor device fabrication process flows.

Since the source of the semiconductor pieces in the reconstituted stiffener ring are from processed devices, the reconstituted stiffener ring may include other structures, layers, dopants, and/or the like in addition to the semiconductor material. For example, backside metallization layers, vias, doped regions, transistors, and/or other circuitry may be present in the semiconductor pieces used in the reconstituted stiffener ring. However, the electrically conductive features, layers, and/or the like may not be electrically coupled to any of the circuitry of the package substrate. That is, such additional features within the semiconductor pieces may be remnants of previous fabrication processes and are substantially non-functional in the reconstituted stiffener ring.

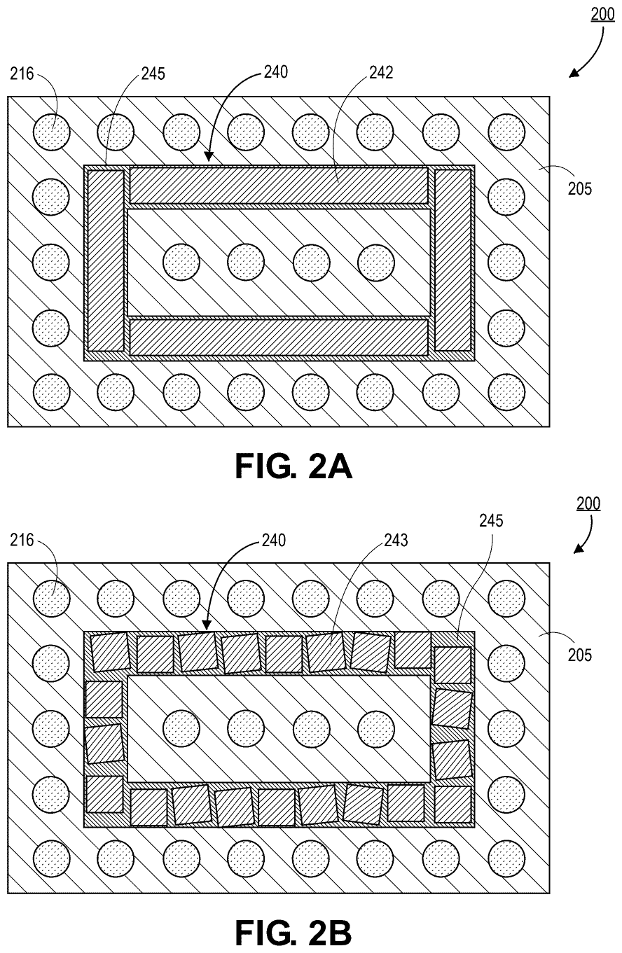

Referring now to FIG. 2A, a plan view illustration of a bottom side of an electronic system 200 is shown, in accordance with an embodiment. The top side of the electronic system 200 may be similar to the electronic system 100 described with respect to FIG. 1. Though, in some embodiments a stiffener (e.g., similar to stiffener 130 above) may be omitted and/or significantly reduced in size. In an embodiment, the bottom side of the electronic system 200 shown in FIG. 2A depicts a bottom of a package substrate 205 that is covered by an array of interconnects 216. The interconnects may be any type of interconnect, such as solder balls, metallic (e.g., copper) bumps, or the like. The interconnects 216 may be power delivery interconnects to provide power to a die (not shown) that is provided on the opposite side of the package substrate 205. The interconnects 216 may also be used for signaling, ground references, and/or the like.

In an embodiment, a reconstituted stiffener 240 is provided on the bottom side of the package substrate 205. In an embodiment, a first portion of the interconnects 216 may be surrounded by the reconstituted stiffener 240, and a second portion of the interconnects 216 may be outside of the reconstituted stiffener 240. In an embodiment, the first portion of the interconnects 216 may be coupled to a die (not shown) that is positioned over the reconstituted stiffener 240. As such, electrical routing through the package substrate 205 between the first portion of the interconnects 216 and the die may be as short as possible. In an embodiment, one or more of the first portion of the interconnects 216 may be power delivery interconnects 216.

In an embodiment, the reconstituted stiffener 240 may comprise semiconductor pieces 242 that are embedded in a matrix 245. The matrix may comprise an epoxy, a mold material, or the like. The matrix 245 may have an outer edge that faces the second portion of the interconnects 216 and an inner edge that faces the first portion of the interconnects 216. In an embodiment, the semiconductor pieces 242 may comprise silicon, or any other semiconductor material typically processed in a wafer format (e.g., III-V semiconductors or the like). In a particular embodiment, the semiconductor pieces 242 comprise the same material used for the die (not shown) on the opposite side of the package substrate 205. The semiconductor pieces 242 may each comprise the same semiconductor material, or the semiconductor pieces 242 may include two or more different types of semiconductor materials.

In an embodiment, the semiconductor pieces 242 may be rejected portions of a semiconductor wafer that have been processed to form other semiconductor devices. For example, the semiconductor pieces 242 may be edge pieces of the semiconductor wafer, rejected portions of the semiconductor wafer, test regions of the semiconductor wafer, and/or the like. Since the semiconductor pieces 242 are sourced from processed wafers, some or all of the semiconductor pieces 242 may have remnants of the semiconductor processing. For example, the semiconductor pieces 242 may comprise metal layers (e.g., from backside metallization), dielectric layers, and/or the like. The semiconductor pieces 242 may also comprise transistors, doped regions, testing structures, alignment structures, and/or the like. That is, in some embodiments, the semiconductor pieces 242 may not be pure semiconductor material. Though, in other instances, the semiconductor pieces 242 may be pure semiconductor material. In an embodiment, the semiconductor pieces 242 may be sourced from different wafers or be from different portions of a single wafer. As such, the semiconductor pieces 242 within a single reconstituted semiconductor stiffener 240 may have different remnant structures.

When the semiconductor pieces 242 include remnants from previous processing, the remnants may be electrically isolated from any other circuitry within the electronic system 200. That is, there may be no electrical coupling between any electrically conductive feature within the semiconductor pieces 242 and the electrical routing within the package substrate 205. As such, the identification of such unused electrical features within the reconstituted semiconductor stiffener 240 may be an indication that embodiments similar those described herein may be used to manufacture the electronic system 200.

In the illustrated embodiment, the semiconductor pieces 242 may have rectangular shapes. For example, each edge of the reconstituted semiconductor stiffener 240 may be formed from a single semiconductor pieces 242. Though, in other embodiments, the semiconductor pieces 242 may be smaller chips and/or fragments. An example of such an embodiment is shown in the plan view illustration of FIG. 2B.

In FIG. 2B, the electronic system 200 is substantially similar to the electronic system 200 in FIG. 2A, with the exception of the reconstituted semiconductor stiffener 240. Instead of larger semiconductor pieces 242 of semiconductor material, semiconductor chips 243 (or fragments) are coupled together as a mosaic structure. For example, a plurality of semiconductor chips 243 may be positioned along each edge of the reconstituted semiconductor stiffener 240. In the illustrated embodiment, each of the semiconductor chips 243 are substantially similar in size and shape. Though, in other embodiments, semiconductor chips 243 with different sizes and/or shapes may be arranged together in order to form the mosaic semiconductor structure of the reconstituted semiconductor stiffener 240. For example, each of the semiconductor chips 243 in FIG. 2B are rectangular, but embodiments may also include one or more semiconductor chips 243 with triangular shapes or any other polygonal shapes. The semiconductor chips 243 may also have different orientations. That is, the semiconductor chips 243 may be rotated so that a pair of neighboring semiconductor chips 243 have nearest edges that are not parallel to each other. Gaps between semiconductor chips 243 may be filled with epoxy or any other suitable matrix material.

In the embodiments shown in FIG. 2A and FIG. 2B, the reconstituted semiconductor stiffener 240 has a relatively high volume percentage of semiconductor material. For example, within a given cross-section of the reconstituted semiconductor stiffener 240, an area of the cross-section that includes semiconductor material may be approximately 75% or higher, approximately 80% or higher, approximately 90% or higher, or approximately 99% or higher. As the area of the cross-section that is semiconductor material increases, the CTE of the reconstituted semiconductor stiffener 240 more closely matches the CTE of the die (not shown) on the opposite side of the package substrate 205. In some instances, higher percentages of semiconductor material may be obtained by closely packing the semiconductor chips 243 together.

In yet another embodiment, the semiconductor chips 243 may be replaced with a semiconductor powder, and the semiconductor powder may be reconstituted into a rigid solid by a matrix material, such as an epoxy or the like. The use of such a semiconductor powder may allow for an even higher volume percentage of semiconductor material. An example of a process for forming a reconstituted semiconductor material with a semiconductor powder and a matrix material is described in greater detail below.

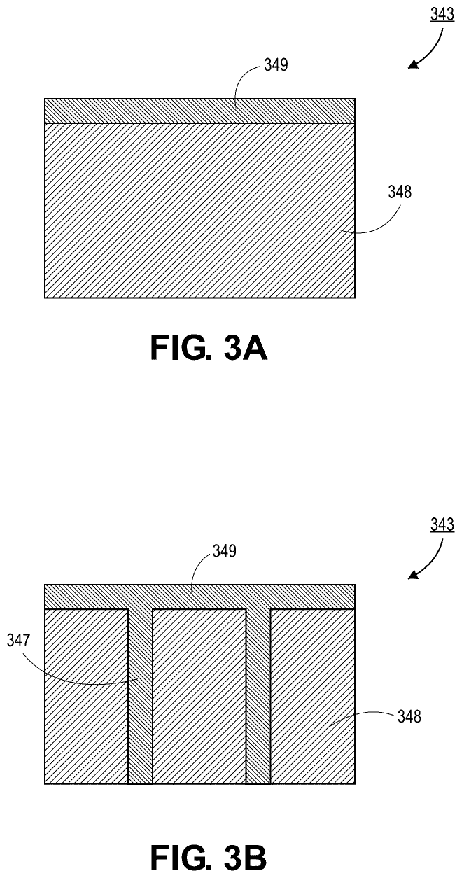

Referring now to FIGS. 3A and 3B, a pair of cross-sectional illustrations depicting portions of semiconductor chips 343 is shown, in accordance with an embodiment. The semiconductor chips 343 may be similar to any of the semiconductor chips 243 and/or semiconductor pieces 242 described in greater detail above. For example, the semiconductor chips 343 may be recycled portions of a wafer that would otherwise be scrapped. Since the semiconductor chips 343 are originally processed as a part of a larger wafer, the semiconductor chips 343 may have features that are remnants of the processing.

For example, in FIG. 3A, the semiconductor chip 343 may have a backside metallization layer 349 on a surface of a semiconductor substrate 348. The backside metallization layer 349 may also comprise one or more dielectric layers (not shown) or the like. As shown in FIG. 3B, the semiconductor chip 343 may further comprise one or more vias 347 (e.g., through silicon vias (TSVs)) that pass at least partially through a thickness of the semiconductor chip 343. In some embodiments, the semiconductor chip 343 may also include transistors, doped regions, traces, and/or any other feature that may be fabricated on a semiconductor substrate 348.

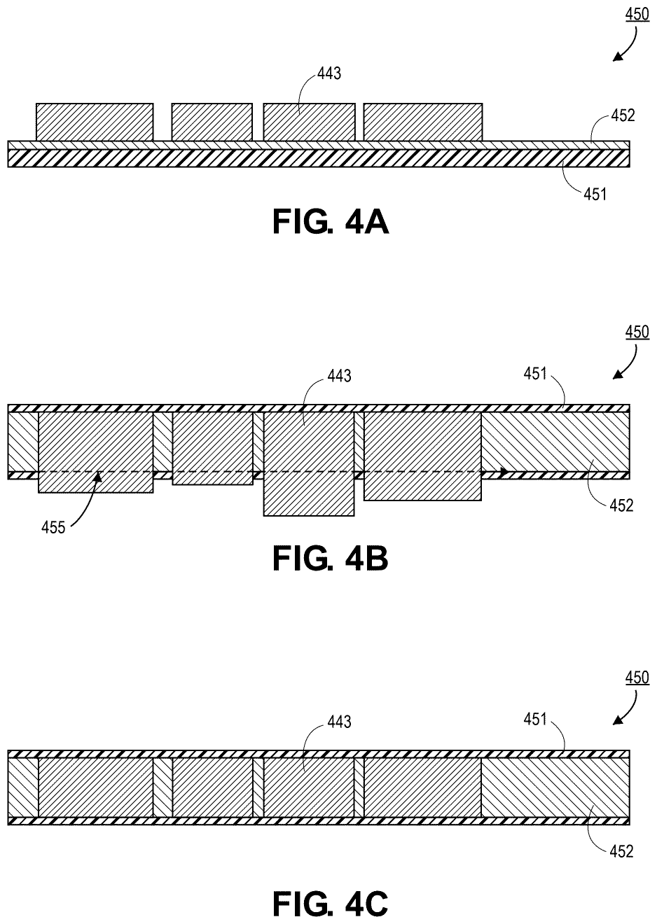

Referring now to FIGS. 4A-4D , a series of illustrations depicting a process for forming reconstituted semiconductor strips 450 that can be used to form reconstituted semiconductor stiffeners is shown, in accordance with an embodiment. In an embodiment, the reconstituted semiconductor strips 450 may be stored (e.g., as a roll or a strip), and the reconstituted semiconductor strips 450 may be trimmed to a desired size and mounted to a package substrate. For example, four reconstituted semiconductor strips 450 may be used to form a rectangular reconstituted semiconductor stiffener similar to any of those described in greater detail herein.

Referring now to FIG. 4A, a side view illustration of the reconstituted semiconductor strip 450 at a stage of manufacture is shown, in accordance with an embodiment. In an embodiment, a tape 451 is provided as an underlying layer, and an adhesive 452 is provided over the tape 451. As shown, a plurality of semiconductor chips 443 may be attached to the adhesive 452. The semiconductor chips 443 may be placed on the adhesive 452 with a pick and place tool, any suitable automated process, a manual process, or the like. In some embodiments, gaps may be provided between the semiconductor chips 443. The gaps between the semiconductor chips 443 may be non-uniform in some embodiments. Other embodiments may have semiconductor chips 443 with a more uniform spacing.

In an embodiment, the semiconductor chips 443 may be similar to any of the semiconductor chips or semiconductor pieces described in greater detail herein. In an embodiment, the semiconductor chips 443 may have non-uniform dimensions. For example, the widths of the semiconductor chips 443 may be different. In some instances, the semiconductor chips 443 may have similar thicknesses (since the semiconductor chips 443 are all sourced from semiconductor wafers that have highly uniform thicknesses). Though, the thicknesses do not need to be the same in some embodiments.

FIG. 4B is a plan view illustration of the reconstituted semiconductor strip 450 in FIG. 4A. As shown, the semiconductor chips 443 may have different areas. For example, some of the semiconductor chips 443 may extend beyond the tape 451. In order to make a uniform reconstituted semiconductor strip 450, a dicing process (e.g., along line 455) may be used in order to trim the semiconductor chips 443 so that they have a uniform width. As shown in FIG. 4B, the semiconductor chips 443 are all lined up along a single edge of the adhesive 452. As such, only a single cut is needed in order to make a reconstituted semiconductor strip 450 with semiconductor chips 443 that have the same width as the adhesive 452. FIG. 4C is a plan view illustration of the reconstituted semiconductor strip 450 after the singulation process.

Referring now to FIG. 4D, a plan view illustration of the reconstituted semiconductor strip 450 after a matrix 445 (e.g., an epoxy or the like) is dispensed around the semiconductor chips 443. In the illustrated embodiment, the top of the semiconductor chips 443 are exposed. Though, in other embodiments, the semiconductor chips 443 may be completely covered by the matrix 445. After the matrix 445 is cured, the tape 451 (and optionally the adhesive 452) may be removed, and the resulting reconstituted semiconductor strip 450 may be used to form a stiffener, similar to any of the reconstituted stiffeners described in greater detail herein.

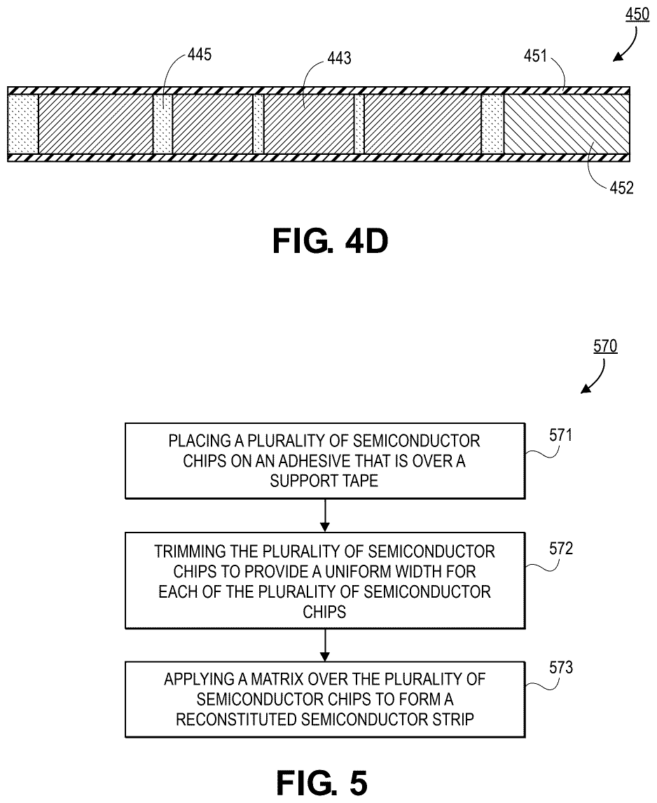

Referring now to FIG. 5, a flow diagram of a process 570 for forming a reconstituted semiconductor strip is shown, in accordance with an embodiment. In an embodiment, the process 570 may be similar to the process described above with respect to FIGS. 4A-4D . In an embodiment, the process 570 may begin with operation 571, which comprises placing a plurality of semiconductor chips on an adhesive that is over a support tape. The semiconductor chips may be recycled pieces of semiconductor material similar to any of the semiconductor chips or pieces described in greater detail herein. The semiconductor chips may be placed on the adhesive with a pick and place tool or any other suitable process.

In an embodiment, the process 570 may continue with operation 572, which comprises trimming the plurality of semiconductor chips to provide a uniform width for each of the plurality of semiconductor chips. The trimming process may include a laser singulation process, a mechanical sawing process, or the like.

In an embodiment, the process 570 may continue with operation 573, which comprises applying a matrix over the plurality of semiconductor chips to form a reconstituted semiconductor strip. The matrix may be an epoxy material or the like. The combined matrix and semiconductor chips may be a solid material that remains attached to the adhesive. The adhesive may then be used to attach the reconstituted semiconductor strip to a package substrate in order to form a reconstituted semiconductor stiffener similar to any of the reconstituted semiconductor stiffeners described in greater detail herein.

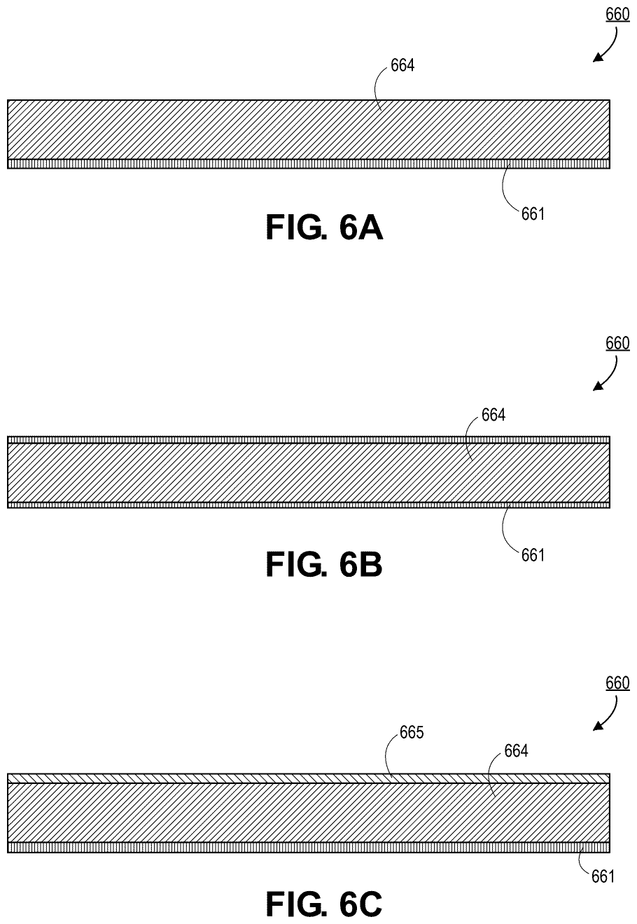

Referring now to FIGS. 6A-6D , a series of illustrations depicting a process for forming a reconstituted semiconductor strip 660 is shown, in accordance with an additional embodiment. In FIG. 6A, a semiconductor powder 664 is applied to a tape 661 (or adhesive). The semiconductor powder 664 may be ground up from rejected pieces of silicon wafers or the like. FIG. 6B is a plan view illustration of the reconstituted semiconductor strip 660 of FIG. 6A.

Referring now to FIG. 6C, a side view of the reconstituted semiconductor strip 660 after an epoxy 665 or the like is applied over the semiconductor powder 664. The epoxy 665 may permeate the semiconductor powder 664 in order to form a solid and stable structure. FIG. 6D is a plan view illustration of the reconstituted semiconductor strip 660 of FIG. 6C. In an embodiment, the reconstituted semiconductor strip 660 can then be used in order to form reconstituted semiconductor stiffeners similar to any of those described in greater detail herein.

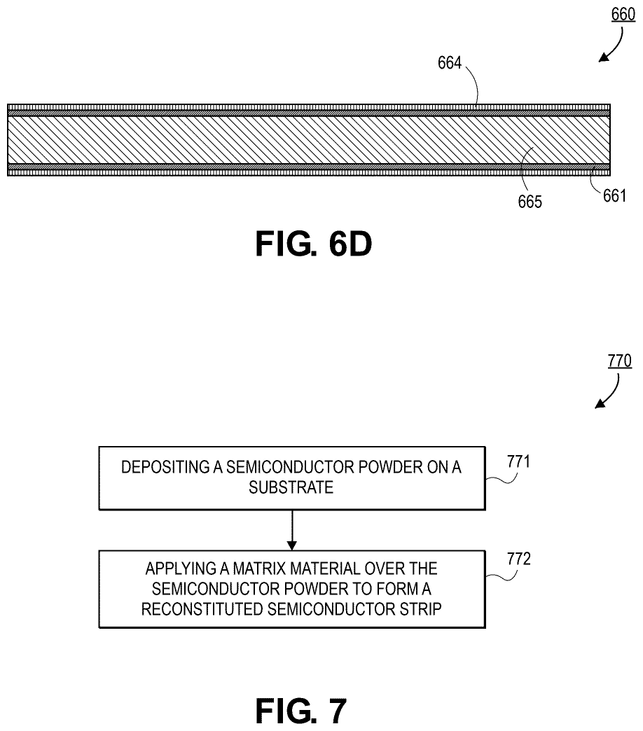

Referring now to FIG. 7, a flow diagram of a process 770 for forming a reconstituted semiconductor strip is shown, in accordance with an embodiment. In an embodiment, the process 770 may be similar to the process described above with respect to FIGS. 6A-6D . In an embodiment, the process 770 may begin with operation 771, which comprises depositing a semiconductor powder on a substrate. The semiconductor powder may be ground up semiconductor material that is waste material from the processing of a semiconductor wafer. In an embodiment, the semiconductor powder may be dispensed on the substrate with a suitable process. The substrate may be an adhesive layer, a tape, or the like.

In an embodiment, the process 770 may continue with operation 772, which comprises applying a matrix material over the semiconductor powder to form a reconstituted semiconductor strip. In an embodiment, the matrix material may be an epoxy or the like. The epoxy may bind the semiconductor powder together in order to form a solid reconstituted semiconductor strip. In an embodiment, the reconstituted semiconductor strip may be used to form a reconstituted semiconductor stiffener similar to any of the reconstituted semiconductor stiffeners described in greater detail herein.

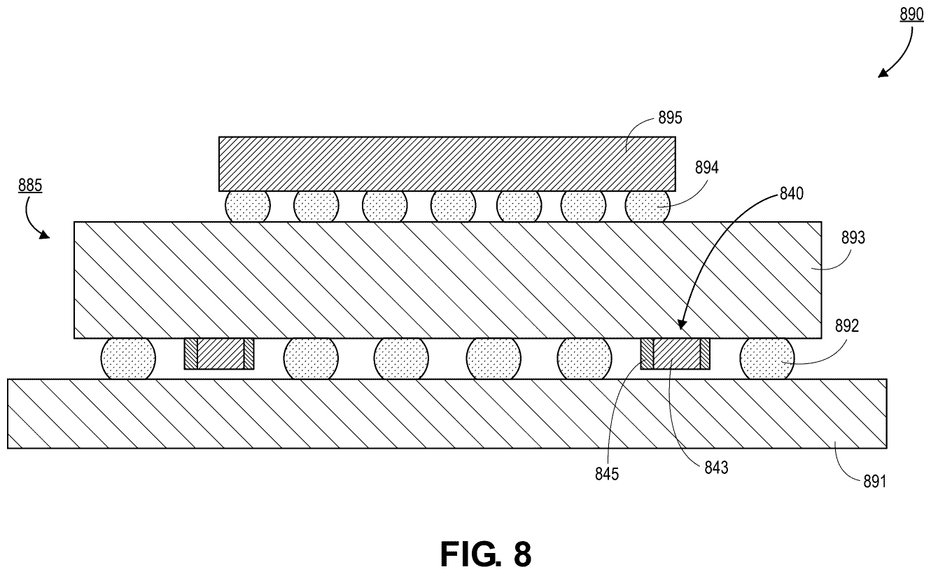

Referring now to FIG. 8, a cross-sectional illustration of an electronic system 890 is shown, in accordance with an embodiment. In an embodiment, the electronic system 890 may comprise a board 891, such as a printed circuit board (PCB), a motherboard, or the like. In an embodiment, the board 891 may be coupled to an electronic package 885 by second level interconnects (SLIs) 892. In an embodiment, the SLIs 892 may comprise solder balls, sockets, or the like.

In an embodiment, the electronic package 885 may comprise a package substrate 893. The package substrate 893 may be similar to any of the package substrates described in greater detail herein. For example, the package substrate 893 may comprise dielectric buildup layers over a core or the package substrate 893 may be coreless.

In an embodiment, a reconstituted semiconductor stiffener 840 may be provided on the bottom surface of the package substrate 893. The reconstituted semiconductor stiffener 840 may be positioned below a die 895. For example, the die 895 may be within a footprint of the reconstituted semiconductor stiffener 840 that is defined by an outer perimeter of the reconstituted semiconductor stiffener 840.

In an embodiment, the reconstituted semiconductor stiffener 840 may be similar to any of the reconstituted semiconductor stiffeners described in greater detail herein. For example, the reconstituted semiconductor stiffener 840 may comprise a plurality of semiconductor chips 843 or pieces that are embedded in a matrix 845, such as an epoxy or the like. The semiconductor chips 843 may be recycled semiconductor chips from a semiconductor wafer that would otherwise be waste products. In an embodiment, the reconstituted semiconductor stiffener 840 may be adhered to the package substrate 893 with an adhesive (not shown) or the like.

In an embodiment, one or more dies 895 may be coupled to the package substrate 893 by first level interconnects (FLIs) 894. The FLIs 894 may be any suitable FLI architecture, such as solder balls, copper bumps, or the like. In an embodiment, the one or more dies 895 may be any type of die (e.g., a processor die (e.g., a central processing unit (CPU), a graphics processing unit (GPU), an XPU), a memory die, a communications die, a power management die, and/or the like). In an embodiment, two or more dies 895 may be electrically coupled together by a bridge (not shown) that is embedded in the package substrate 893 or provided over the package substrate 893.

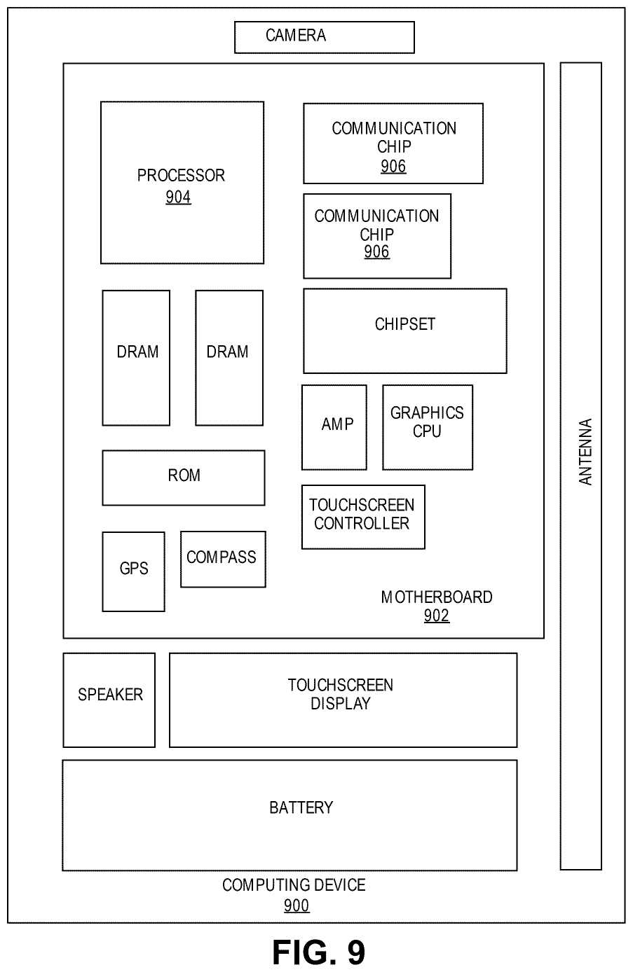

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904. In an embodiment, a device package is coupled to the board 902. One or both of the processor 904 or the communication chip 906 may be coupled to the board 902 through the device package.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor may be part of a package substrate with a reconstituted semiconductor stiffener that is provided on a bottom surface of the package substrate, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the disclosure, the integrated circuit die of the communication chip may be part of a package substrate with a reconstituted semiconductor stiffener that is provided on a bottom surface of the package substrate, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### EXAMPLES

Example 1: an apparatus, comprising: a substrate; and a ring on the substrate, wherein the ring comprises: a matrix material; and a plurality of semiconductor chips embedded in the matrix material.

Example 2: the apparatus of Example 1, further comprising: a first plurality of interconnects surrounded by the ring on the substrate; and a second plurality of interconnects outside an outer perimeter of the ring.

Example 3: the apparatus of Example 2, further comprising: a die on a surface of the substrate opposite from the ring, wherein the substrate is at least partially over a footprint of the ring.

Example 4: the apparatus of Examples 1-3, wherein the plurality of semiconductor chips comprise silicon.

Example 5: the apparatus of Examples 1-4, wherein one or more of the plurality of semiconductor chips comprise a backside metallization layer.

Example 6: the apparatus of Examples 1-5, wherein one or more of the plurality of semiconductor chips comprise a via at least partially through a thickness of each of the one or more of the plurality of semiconductor chips.

Example 7: the apparatus of Examples 1-6, wherein two or more of the plurality of semiconductor chips comprise different dimensions.

Example 8: the apparatus of Examples 1-7, wherein two or more of the plurality of semiconductor chips comprise different orientations.

Example 9: the apparatus of Examples 1-8, wherein the matrix material comprises an epoxy.

Example 10: the apparatus of Examples 1-9, wherein the plurality of semiconductor chips occupy at least 80% of a cross-sectional area of the ring.

Example 11: an apparatus, comprising: substrate; a reconstituted semiconductor stiffener ring on the substrate, wherein the reconstituted semiconductor stiffener ring comprises: a plurality of dies comprising silicon, wherein the plurality of dies are arranged in a rectangular pattern with an individual die along each edge of the rectangular pattern; and a matrix material around the plurality of dies.

Example 12: the apparatus of Example 11, wherein the plurality of dies comprise a conductive layer.

Example 13: the apparatus of Example 12, wherein the conductive layer is a backside metallization layer or a via.

Example 14: the apparatus of Examples 11-13, wherein the plurality of dies are electrically isolated from circuitry embedded within the substrate.

Example 15: the apparatus of Examples 11-14, wherein the substrate is a package substrate comprising dielectric buildup layers.

Example 16: the apparatus of Examples 11-15, further comprising: a device die on a surface of the substrate opposite from the reconstituted semiconductor stiffener ring, and wherein the device die is provided over at least a portion of a footprint of the reconstituted semiconductor stiffener ring defined by an outer perimeter of the reconstituted semiconductor stiffener ring.

Example 17: the apparatus of Examples 11-16, wherein the plurality of dies are die fragments.

Example 18: an apparatus, comprising: a matrix material with a ring shape that comprises an outer perimeter and an inner perimeter to define a frame shape; and a semiconductor material embedded within the matrix material, wherein a total area of the semiconductor material within a cross-section through the matrix material and the semiconductor material occupies at least 80% of a total area the cross-section.

Example 19: the apparatus of Example 18, wherein the semiconductor material is a semiconductor powder.

Example 20: the apparatus of Example 18 or Example 19, wherein the semiconductor material comprises a plurality of semiconductor chips.

What is claimed is:

1. An apparatus, comprising:
a substrate; and
a ring on the substrate, wherein the ring comprises:
a matrix material; and
a plurality of semiconductor chips embedded in the matrix material.

2. The apparatus of claim 1, further comprising:
a first plurality of interconnects surrounded by the ring on the substrate; and
a second plurality of interconnects outside an outer perimeter of the ring.

3. The apparatus of claim 2, further comprising:
a die on a surface of the substrate opposite from the ring, wherein the substrate is at least partially over a footprint of the ring.

4. The apparatus of claim 1, wherein the plurality of semiconductor chips comprise silicon.

5. The apparatus of claim 1, wherein one or more of the plurality of semiconductor chips comprise a backside metallization layer.

6. The apparatus of claim 1, wherein one or more of the plurality of semiconductor chips comprise a via at least partially through a thickness of each of the one or more of the plurality of semiconductor chips.

7. The apparatus of claim 1, wherein two or more of the plurality of semiconductor chips comprise different dimensions.

8. The apparatus of claim 1, wherein two or more of the plurality of semiconductor chips comprise different orientations.

9. The apparatus of claim 1, wherein the matrix material comprises an epoxy.

10. The apparatus of claim 1, wherein the plurality of semiconductor chips occupy at least 80% of a cross-sectional area of the ring.

11. An apparatus, comprising:
substrate;
a reconstituted semiconductor stiffener ring on the substrate, wherein the reconstituted semiconductor stiffener ring comprises:
a plurality of dies comprising silicon, wherein the plurality of dies are arranged in a rectangular pattern with an individual die along each edge of the rectangular pattern; and
a matrix material around the plurality of dies.

12. The apparatus of claim 11, wherein the plurality of dies comprise a conductive layer.

13. The apparatus of claim 12, wherein the conductive layer is a backside metallization layer or a via.

14. The apparatus of claim 11, wherein the plurality of dies are electrically isolated from circuitry embedded within the substrate.

15. The apparatus of claim 11, wherein the substrate is a package substrate comprising dielectric buildup layers.

16. The apparatus of claim 11, further comprising:
a device die on a surface of the substrate opposite from the reconstituted semiconductor stiffener ring, and wherein the device die is provided over at least a portion of a footprint of the reconstituted semiconductor stiffener ring defined by an outer perimeter of the reconstituted semiconductor stiffener ring.

17. The apparatus of claim 11, wherein the plurality of dies are die fragments.

18. An apparatus, comprising:
a matrix material with a ring shape that comprises an outer perimeter and an inner perimeter to define a frame shape; and
a semiconductor material embedded within the matrix material, wherein a total area of the semiconductor material within a cross-section through the matrix material and the semiconductor material occupies at least 80% of a total area the cross-section.

19. The apparatus of claim 18, wherein the semiconductor material is a semiconductor powder.

20. The apparatus of claim 18, wherein the semiconductor material comprises a plurality of semiconductor chips.
